(19) United States
(12) Patent Application Publication
(10) Pub. No.: US 2026/0352188 A1
(43) Pub. Date: Nov. 5, 2026

(54) MODULATION OF ELECTRICAL SIGNAL TO TRANSMIT POWER, DATA, AND CLOCK SIGNAL BETWEEN A PRIMARY SIDE AND A SECONDARY SIDE OF A TRANSFORMER

(71) Applicant: Microchip Technology Inc., Chandler, AZ (US)

(72) Inventor: Stefan Weiers, Heidelberg (DE)

(73) Assignee: Microchip Technology Inc., Chandler, AZ (US)

(21) Appl. No.: 19/267,730

(22) Filed: Jul. 14, 2025

Related U.S. Application Data
(60) Provisional application No. 63/798,257, filed on May 1, 2025.

(51) Int. Cl. H03K 3/017

(52) U.S. Cl. CPC H03K 3/017

(57) ABSTRACT

A system and method for modulating an electrical signal to transmit power and data and clock signals between a primary side and a secondary side of a transformer are disclosed. The method may include generating an electrical signal to transmit a data signal and a clock signal from a primary side circuit of a transformer to a secondary side circuit of the transformer. The method may also include modulating the electrical signal, wherein the electrical signal is symmetrically modulated when the data signal is in an idle state and is asymmetrically modulated when the data signal is in an active state. The method may also include transmitting the electrical signal from the primary side circuit to the secondary side circuit.

### PRIORITY

This application claims priority to U.S. Provisional Patent Application No. 63/798,257 filed May 1, 2025, the contents of which are hereby incorporated in their entirety.

### TECHNICAL FIELD

The present disclosure relates to power and data transmission in a transformer, and in particular, to a system and method for modulating an electrical signal to transmit power and data and clock signals between a primary side and a secondary side of a transformer.

### BACKGROUND

In a transformer, the term “primary side” refers to the input section, where electrical energy is supplied to the transformer, typically from a power source. Conversely, the “secondary side” is the output section, connected to the load that will consume the electrical energy. There is no direct electrical connection between the primary and secondary sides; energy is transferred solely through the magnetic field, providing electrical isolation.

A circuit may also include a microcontroller to communicate data and reference clock signals from the primary side to the secondary side through an isolation barrier. To transmit the data and clock signals through the isolation barrier, a circuit may use an optocoupler, a fast data coupler, frequency shift keying, or amplitude shift keying.

### SUMMARY OF THE INVENTION

Aspects provide systems and methods for modulating an electrical signal to transmit power and data and clock signals between a primary side and a secondary side of a transformer. Examples of the present disclosure may include a transformer. The transformer may include a primary side circuit. The transformer may also include a secondary side circuit. The transformer may further include a control circuit communicatively coupled to the primary side circuit. The control circuit may be to generate an electrical signal to transmit a data signal and a clock signal from the primary side circuit to the secondary side circuit. The control circuit may also be to modulate the electrical signal, wherein the electrical signal is symmetrically modulated when the data signal is in an idle state and is asymmetrically modulated when the data signal is in an active state. The control circuit may further be to transmit the electrical signal from the primary side circuit to the secondary side circuit.

In combination with any of the above examples, the control circuit may be to align an edge of the electrical signal to a clock cycle.

In combination with any of the above examples, the electrical signal may be asymmetrically modulated according to an alternating current free modulation scheme.

In combination with any of the above examples, the primary side circuit may include a pulse width modulation (PWM) circuit to modulate the electrical signal.

In combination with any of the above examples, the transformer may include a second primary side circuit. The transformer may also include a second secondary side circuit. The control circuit may be communicatively coupled to the second primary side circuit. The control circuit may be to generate a second electrical signal to transmit a second data signal and the clock signal from the second primary side circuit to the second secondary side circuit. The control circuit may also be to modulate the second electrical signal. The control circuit may further be to transmit the second electrical signal from the second primary side circuit to the second secondary side circuit.

Alone or in combination with any of the above examples, examples of the present disclosure may include a transformer. The transformer may include a primary side circuit. The transformer may also include a secondary side circuit. The transformer may further include a control circuit communicatively coupled to the secondary side circuit. The control circuit may be to switch the secondary side circuit to a first load state to indicate an idle state of a data signal provided from the secondary side circuit to the primary side circuit. The control circuit may also be to switch the secondary side circuit to a second load state to indicate an active state of the data signal. Switching between the first load state and the second load state may be based on a bit line coding scheme.

In combination with any of the above examples, the bit line coding scheme may contain at least one bit more than the data signal.

In combination with any of the above examples, the secondary side circuit may be in the first load state for a time period less than a predetermined portion of an operating time of the secondary side circuit.

In combination with any of the above examples, switching between the first load state and the second load state may use on-off keying.

In combination with any of the above examples, switching between the first load state and the second load state may be synced to a clock signal from the primary side circuit.

Alone or in combination with any of the above examples, examples of the present disclosure may include a method. The method may include generating an electrical signal to transmit a data signal and a clock signal from a primary side circuit of a transformer to a secondary side circuit of the transformer. The method may also include modulating the electrical signal, wherein the electrical signal is symmetrically modulated when the data signal is in an idle state and is asymmetrically modulated when the data signal is in an active state. The method may also include transmitting the electrical signal from the primary side circuit to the secondary side circuit.

In combination with any of the above examples, the method may include aligning an edge of the electrical signal to a clock cycle.

In combination with any of the above examples, the electrical signal may be asymmetrically modulated according to an alternating current free modulation scheme.

In combination with any of the above examples, the method may include using a pulse width modulation (PWM) circuit to modulate the electrical signal.

In combination with any of the above examples, the method may include generating a second electrical signal to transmit a second data signal and the clock signal from a second primary side circuit of a second transformer to a second secondary side circuit of the second transformer. The method may also include modulating the second electrical signal. The method may further include transmitting the second electrical signal from the second primary side circuit to the second secondary side circuit.

Alone or in combination with any of the above examples, examples of the present disclosure may include a method. The method may include switching a secondary side circuit to a first load state to indicate an idle state of a data signal provided from the secondary side circuit to a primary side circuit. The method may also include switching the secondary side circuit to a second load state to indicate an active state of the data signal. Switching between the first load state and the second load state may be based on a bit line coding scheme.

In combination with any of the above examples, the bit line coding scheme may contain at least one bit more than the data signal.

In combination with any of the above examples, the secondary side circuit may be in the first load state for a time period less than a predetermined portion of an operating time of the secondary side circuit.

In combination with any of the above examples, switching between the first load state and the second load state may use on-off keying.

In combination with any of the above examples, switching between the first load state and the second load state may be synced to a clock signal from the primary side circuit.

### BRIEF DESCRIPTION OF THE DRAWINGS

The figures illustrate examples of systems and methods for modulating an electrical signal to transmit power and data and clock signals between a primary side and a secondary side of a transformer.

FIG. 1 illustrates a block diagram for a transformer modulating an electrical signal to transmit power and data and clock signals between a primary side and a secondary side of a transformer, according to examples of the present disclosure;

FIG. 2 illustrates a graph of a transmission coding scheme for modulating an electrical signal to transmit power and data and clock signals between a primary side and a secondary side of a transformer, according to examples of the present disclosure;

FIG. 3 illustrates a block diagram for a system for modulating an electrical signal to transmit power and data and clock signals between a primary side and a secondary side of a transformer, according to examples of the present disclosure;

FIG. 4 illustrates a flowchart of a method for transmitting an electrical signal from a primary side circuit to a secondary side circuit of a transformer to transmit power and data and clock signals, according to examples of the present disclosure; and

FIG. 5 illustrates a flowchart of a method for transmitting an electrical signal from a secondary side circuit to a primary side circuit of a transformer to transmit a data signal, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, systems and methods for modulating an electrical signal to transmit power and data and clock signals between a primary side and a secondary side of a transformer are provided. The disclosed systems and methods may provide data transmission between the primary side and the secondary side of the transformer at a data rate at the level of the power transformer clock (e.g., up to two megabits per second (Mbit/s)). Additionally, the disclosed systems and methods may provide a reference clock while not using additional hardware for modulation and demodulation (e.g., core independent peripherals (CIPs)). The disclosed systems and methods may be used for a variety of applications including, but not limited to, high side shunt current sensors (e.g., for power metering), isolated control panels, and swivel joint replacements. Further, because the disclosed transformer has a control circuit (e.g., microcontroller) on both the primary and secondary sides, the functional safety (FuSa) of the system in which the transformer is included may be improved.

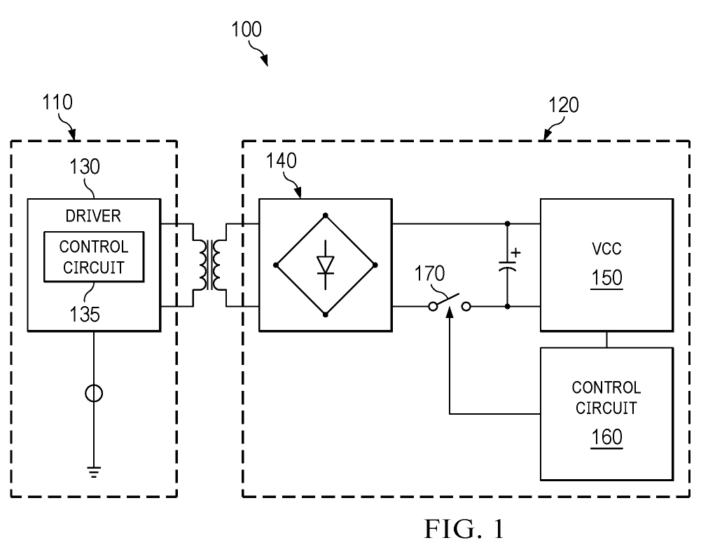

FIG. 1 illustrates a block diagram for a transformer modulating an electrical signal to transmit power and data and clock signals between a primary side and a secondary side of a transformer, according to examples of the present disclosure. Transformer 100 may include primary side circuit 110 and secondary side circuit 120. Primary side circuit 110 may include driver 130. Secondary side circuit 120 may include rectifier 140, voltage conditioning circuit (VCC) 150, and control circuit 160. The elements of transformer 100 are an example implementation. Transformer 100 may include more or fewer components. For example, rectifier 140 and VCC 150 may be optional in a transformer implementing the functionality described herein.

Driver 130 may be responsible for controlling the electrical energy supplied to the primary winding of transformer 100. Driver 130 may include switching elements, such as metal-oxide-semiconductor field-effect transistors (MOSFETs) or insulated-gate bipolar transistor (IGBTs), and control circuit 135. Driver 130 may take an input voltage (e.g., direct current (DC)) or rectified alternating current (AC)) and modulate the input voltage before energizing the primary winding of transformer 100. As described in further detail below, the modulation of the input voltage may provide a data signal and a reference clock signal to secondary side circuit 120.

Control circuit 135 may be implemented by instructions for execution by a processor, analog circuitry, digital circuitry, control logic, digital logic circuits programmed through hardware description language, application specific integrated circuits (ASIC), field programmable gate arrays (FPGA), programmable logic devices (PLD), or any suitable combination thereof, whether in a unitary device or spread over several devices. Control circuit 135 may be implemented by instructions for execution by a processor through, for example, a function, application programming interface (API) call, script, program, compiled code, interpreted code, binary, executable, executable file, firmware, object file, container, assembly code, or object.

Rectifier 140 may convert the alternating current output of the transformer into direct current. Rectifier 140 may be any suitable rectifier, such as a half-wave, full-wave center-tapped, or full-wave bridge rectifier. VCC 150 may be receive the direct current voltage from rectifier 140 and may provide voltage to subsequent parts of secondary side circuit 120 (e.g., control circuit 160).

Control circuit 160 may manage and monitor the functions of secondary side circuit 120. Additionally, control circuit 160 may provide communication back to primary side circuit 110 by turning a load of secondary side circuit 120 on or off or by switching between two different load states. For example, control circuit 160 may control the position of switch 170 to turn the load on and off. Control circuit 160 may use on-off keying (OOK) to open and close switch 170 to transmit data signals from secondary side circuit 120 to primary side circuit 110 as described in more detail below.

Control circuit 160 may be implemented by instructions for execution by a processor, analog circuitry, digital circuitry, control logic, digital logic circuits programmed through hardware description language, application specific integrated circuits (ASIC), field programmable gate arrays (FPGA), programmable logic devices (PLD), or any suitable combination thereof, whether in a unitary device or spread over several devices. Control circuit 160 may be implemented by instructions for execution by a processor through, for example, a function, application programming interface (API) call, script, program, compiled code, interpreted code, binary, executable, executable file, firmware, object file, container, assembly code, or object.

Therefore, data may be transmitted bidirectionally between primary side circuit 110 and secondary side circuit 120 (e.g., both the transmit and the receive data signals are exchanged between primary side circuit 110 and secondary side circuit 120). Data may be exchanged at a data rate similar to the level of the transformer clock, which is approximately ten to twenty times faster than alternative ways of data exchange between primary side circuit 110 and secondary side circuit 120 (e.g., using frequency shift keying or amplitude shift keying). As explained in further detail below, the modulation scheme of the electrical energy used to provide power from primary side circuit 110 to secondary side circuit 120 may also be used to transmit data and the reference clock signal using an invariable (e.g., fixed) fundamental frequency, average direct current (DC) free, and transmit one clock edge at a fixed time.

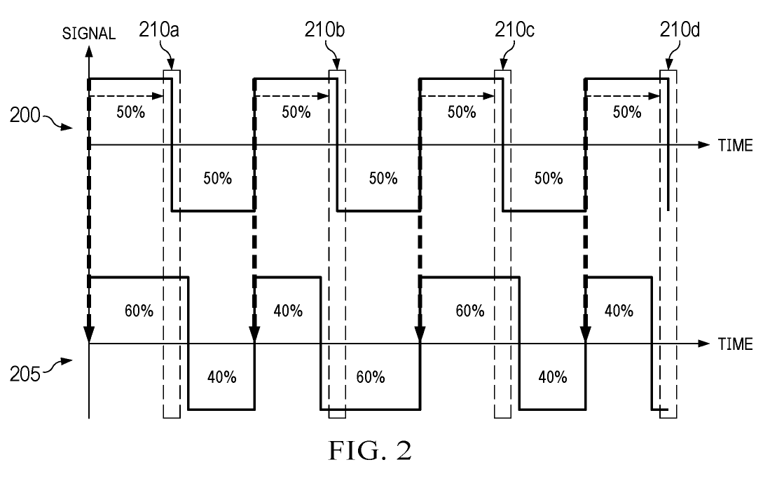

FIG. 2 illustrates a graph of a transmission coding scheme for modulating an electrical signal to transmit power and data and clock signals between a primary side and a secondary side of a transformer, according to examples of the present disclosure. The driver on the primary side circuit (e.g., driver 130 shown in FIG. 1) transmits the electrical energy in one of two states, an idle state (e.g., “0”) and an active state (e.g., “1”). The signals corresponding to the states may be generated by a pulse width modulation (PWM) circuit in the driver. A PWM circuit may generate a variable-width pulse of electrical energy that toggles between a high value and a low value.

Graph 200 represents a modulated electrical signal in an idle state. When driven in the idle state, the electrical energy may be modulated such that the signal is symmetrically modulated (e.g., having a high value 50% of the time and a low value 50% of the time). Graph 205 represents a modulated electrical signal in an active state. When driven in the active state, the electrical energy may be modulated such that the signal is asymmetrically modulated. In the example shown in graph 205, the signal has a high value 60% of the time and has a low value 40% of the time. However, other modulation schemes may be used such as, but not limited to, having a high value 70% of the time and a low value 30% of the time, having a high value 40%of the time and a low value 60% of the time, or having a high value 30% of the time and a low value 70% of the time. The electrical energy in the active state, because it is asymmetric, may be an alternative current (AC) free signal and may avoid saturation effects in the transformer (e.g., transformer 100 shown in FIG. 1). The electrical energy in the idle state and electrical energy in the active state may be average direct current balanced signals.

To provide a reference clock signal from the primary side circuit to the secondary side circuit, an edge of the electrical energy in the idle state and an edge of the electrical energy in the active state may be synchronized. In the example shown in FIG. 2, the rising edges of the electrical energy in the idle state, shown in graph 200, and the rising edges of the electrical energy in the active state, shown in graph 205, are synchronized. In another example, the trailing edges of the electrical energy in the idle state and the trailing edges of the electrical energy in the active state may be synchronized. The edges of the electrical energy may indicate the beginning of a reference clock cycle. The control circuit of the secondary side circuit may interpret the edges of the electrical energy it receives from the primary side circuit as the reference clock signal. The control circuit of the secondary side circuit may use the reference clock signal for clock recovery.

To provide a data signal from the primary side circuit to the secondary side circuit, a control circuit on the secondary side, such as control circuit 160 shown in FIG. 1, may wait a predetermined period of time from the rising or trailing edge and start detection window 210. Detection window 210 may repeated on a periodic basis, resulting in multiple detection windows 210a, 210b, 210c, and 210d separated by the predetermined period of time. The length of detection windows 210 may be predetermined. The control circuit may determine whether the electrical energy transitions from a high state to a low state during detection window 210 and use that determination to indicate a data signal from the primary side circuit. Specifically, when the control circuit detects a transition within detection window 210, the driver of the primary side circuit is transmitting electrical energy in the idle state. When the control circuit does not detect a transition within detection window 210, the driver of the primary side circuit is transmitting electrical energy in the active state. In some examples, the control circuit may include an PWM circuit and a core independent peripheral (CIP) circuit and use these circuits to interpret the data signal based on the received electrical energy.

To transmit data from the secondary side circuit to the primary side circuit, the control circuit of the secondary side circuit may turn a load on the secondary side circuit on and off or switch between two different load states. For example, the control circuit of the secondary side circuit may use on-off keying (OOK) to control the position of a switch (e.g., switch 170 shown in FIG. 1) of the secondary side circuit to turn a load on and off. OOK is a modulation technique used for data communication. OOK transmits data by using the presence or absence of a signal. The presence of a signal represents a binary one and the absence of a signal represents a binary 0.

When the control circuit closes the switch, electrical energy may flow through the secondary side circuit. When the control circuit opens the switch, electrical energy may not flow through the secondary side circuit. A control circuit on the primary side circuit (e.g., control circuit 135 shown in FIG. 1) may interpret the flow of electrical energy as indicating that the secondary side circuit is communicating an idle state. Correspondingly, the control circuit on the primary side circuit may interpret the absence of the flow of electrical energy as indicating that the secondary side circuit is communicating an active state.

The control circuit of the secondary side circuit may synchronize the OOK with the reference clock signal. For example, the control circuit may close the switch for a first clock period and open the switch for a second clock period.

The control circuit of the secondary side circuit may utilize a line coding scheme to ensure that the maximum off time for the switch in a first load state (e.g., off or in a light load state) does not exceed a predetermined portion of the operating time of the secondary side circuit to prevent power interruptions to the control circuit. This condition may be fulfilled by an N+1 coding scheme, where N is the number of bits per data word. With this type of coding, the maximum off time may be not more than fifty percent of the operating time.

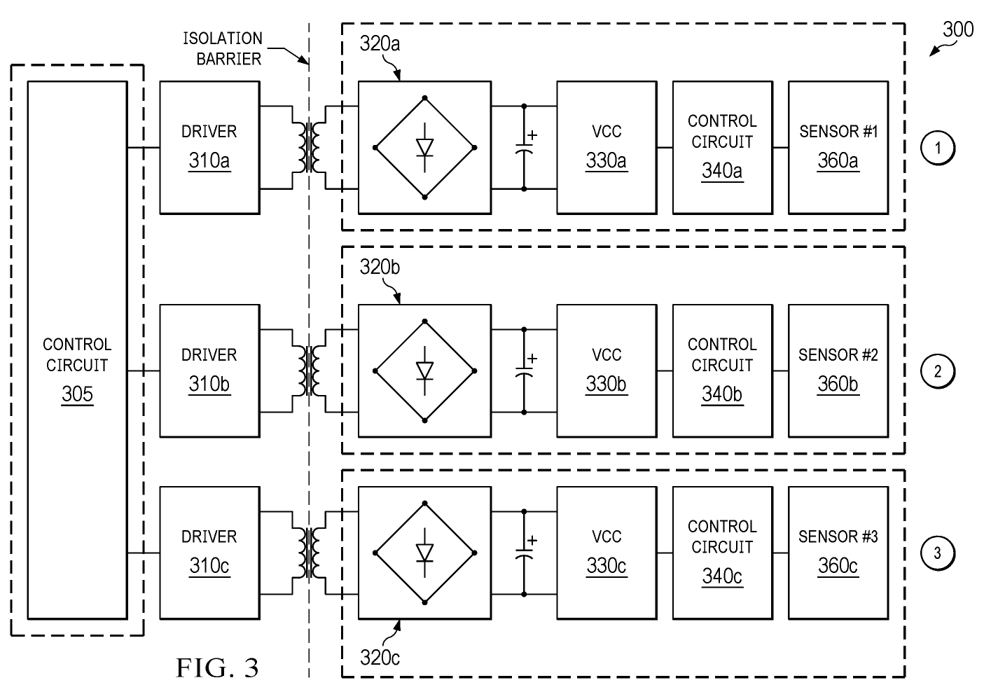

FIG. 3 illustrates a block diagram for a system for modulating an electrical signal to transmit power and data and clock signals between a primary side and a secondary side of a transformer, according to examples of the present disclosure. In system 300, control circuit 305 (e.g., a microcontroller) may be communicatively coupled to multiple drivers (e.g., drivers 310a, 310b, and 310c). Each of drivers 310a, 310b, and 310c may be similar to driver 130 shown in FIG. 1. Control circuit 305 and drivers 310a, 310b, and 310c may form a portion of the primary side circuit of a transformer.

Driver 310a may correspond to rectifier 320a, VCC 330a, control circuit 340a, and sensor 360a on the secondary side of the transformer. Rectifier 320a, VCC 330a, and control circuit 340a may be similar to rectifier 140, VCC 150, and control circuit 160, respectively, shown in FIG. 1. Data communication between driver 310a and rectifier 320a, VCC 330a, control circuit 340a, and sensor 360a may form a first data communication channel.

Driver 310b may correspond to rectifier 320b, VCC 330b, control circuit 340b, and sensor 360b on the secondary side of the transformer. Rectifier 320b, VCC 330b, and control circuit 340b may be similar to rectifier 140, VCC 150, and control circuit 160, respectively, shown in FIG. 1. Data communication between driver 310b and rectifier 320b, VCC 330b, control circuit 340b, and sensor 360b may form a second data communication channel.

Driver 310c may correspond to rectifier 320c, VCC 330c, control circuit 340c, and sensor 360c on the secondary side of the transformer. Rectifier 320c, VCC 330c, and control circuit 340c may be similar to rectifier 140, VCC 150, and control circuit 160, respectively, shown in FIG. 1. Data communication between driver 310c and rectifier 320c, VCC 330c, control circuit 340c, and sensor 360c may form a third data communication channel. The first, second, and third data communications channels may be separate and independent from one another.

While three communication channels are shown in FIG. 3, system 300 may include more or fewer communication channels.

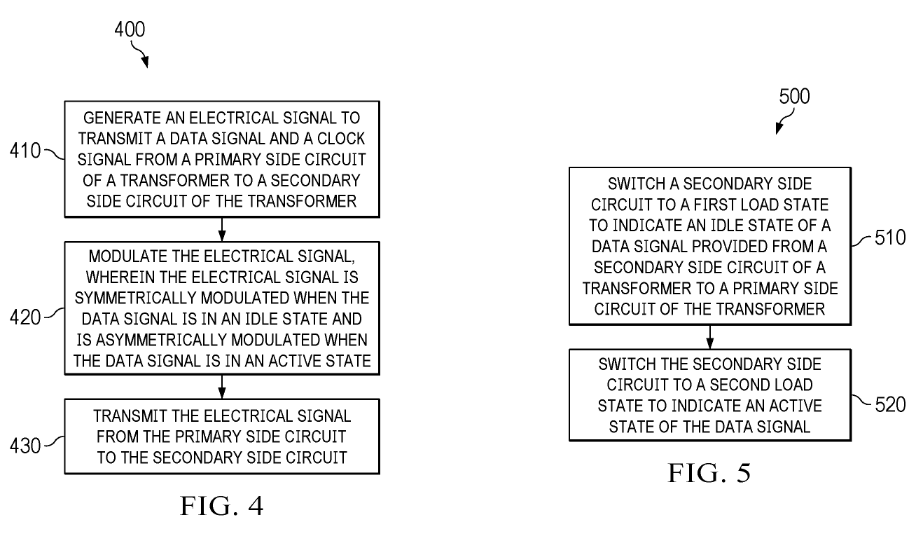

FIG. 4 illustrates a flowchart of a method for transmitting an electrical signal from a primary side circuit to a secondary side circuit of a transformer to transmit power and data and clock signals, according to examples of the present disclosure. Method 400 may be at least partially implemented by a control circuit (e.g., control circuit 135 or control circuit 305 shown in FIGS. 1 and 3, respectively). The control circuit may be implemented by instructions for execution by a processor, analog circuitry, digital circuitry, control logic, digital logic circuits programmed through hardware description language, ASIC, FPGA, PLD, or any suitable combination thereof, whether in a unitary device or spread over several devices. The control circuit may be implemented by instructions for execution by a processor through, for example, a function, API call, script, program, compiled code, interpreted code, binary, executable, executable file, firmware, object file, container, assembly code, or object. For example, the control circuit may be implemented by instructions stored in a non-transitory medium such as a memory that, when loaded and executed by a processor such as a CPU (or any other suitable process), or any other system operable to implement method 400.

Method 400 may begin at block 410 where the control circuit may generate an electrical signal to transmit a data signal and a clock signal from a primary side circuit of a transformer to a secondary side circuit of the transformer. The control circuit may be communicatively coupled to a driver and instruct the driver to generate an input voltage (e.g., DC) or rectified AC).

At block 420, the control circuit may modulate the electrical signal. The electrical signal may be symmetrically modulated when the data signal is in an idle state and is asymmetrically modulated when the data signal is in an active state. The control circuit may instruct the driver to modulate the input voltage generated at block 410 before energizing the primary winding of the transformer. The control circuit may modulate the electrical signal using a PWM circuit. When the modulated signal is in an idle state, the electrical energy may be modulated such that the signal is symmetrically modulated (e.g., having a high value 50% of the time and a low value 50% of the time). When the modulated signal is in an active state, the electrical energy may be modulated such that the signal is asymmetrically modulated. The modulation scheme of the electrical energy in the active state, because it is asymmetric, may be an alternative current free modulation scheme and may avoid saturation effects in the transformer.

To provide a reference clock signal from the primary side circuit to the secondary side circuit, an edge of the electrical energy in the idle state and an edge of the electrical energy in the active state may be aligned. The edges of the electrical energy may indicate the beginning of a reference clock cycle. The control circuit of the secondary side circuit may interpret the edges of the electrical energy it receives from the primary side circuit as the reference clock signal. The control circuit of the secondary side circuit may use the reference clock signal for clock recovery.

At block 430, the control circuit may transmit the electrical signal from the primary side circuit to the secondary side circuit. The modulation scheme of the electrical signal may communicate power, data, and a clock signal to the secondary side circuit.

In some examples, the control circuit may be communicatively coupled to a second primary side circuit (including a second driver) which may be communicatively coupled to a second secondary side circuit. The control circuit may repeat the steps of method 400 to communicate power, data, and a clock signal to the second secondary side circuit. For example, the control circuit may generate a second electrical signal to transmit a second data signal and the clock signal from the second primary side circuit to the second secondary side circuit (block 410), modulate the second electrical signal (block 420), and transmit the second electrical signal from the second primary side circuit to the second secondary side circuit (block 430).

Although FIG. 4 discloses a particular number of operations related to method 400, method 400 may be executed with greater or fewer operations than those depicted in FIG. 4. In addition, although FIG. 4 discloses a certain order of operations to be taken with respect to method 400, the operations comprising method 400 may be completed in any suitable order.

FIG. 5 illustrates a flowchart of a method for transmitting an electrical signal from a secondary side circuit to a primary side circuit of a transformer to transmit a data signal, according to examples of the present disclosure. Method 500 may be at least partially implemented by a control circuit (e.g., control circuit 160 or control circuit 340a, 340b, or 340c shown in FIGS. 1 and 3, respectively). The control circuit may be implemented by instructions for execution by a processor, analog circuitry, digital circuitry, control logic, digital logic circuits programmed through hardware description language, ASIC, FPGA, PLD, or any suitable combination thereof, whether in a unitary device or spread over several devices. The control circuit may be implemented by instructions for execution by a processor through, for example, a function, API call, script, program, compiled code, interpreted code, binary, executable, executable file, firmware, object file, container, assembly code, or object. For example, the control circuit may be implemented by instructions stored in a non-transitory medium such as a memory that, when loaded and executed by a processor such as a CPU (or any other suitable process), or any other system operable to implement method 500.

Method 500 may begin at block 510 where the control circuit may switch the secondary side circuit to a first load state to indicate an idle state of a data signal provided from the secondary side circuit to the primary side circuit. To switch to a first load state, the control circuit of the secondary side circuit may turn a load on the secondary side circuit on or switch to a load state of a first level. For example, the control circuit of the secondary side circuit may use on-off keying (OOK) to control the position of a switch (e.g., switch 170 shown in FIG. 1) of the secondary side circuit to place the secondary side circuit in a first load state.

At block 520, the control circuit may switch the secondary side circuit to a second load state to indicate an active state of the data signal. To switch to a second load state, the control circuit of the secondary side circuit may turn a load on the secondary side circuit off or switch to a load state of a second level. For example, the control circuit of the secondary side circuit may use on-off keying (OOK) to control the position of a switch (e.g., switch 170 shown in FIG. 1) of the secondary side circuit to place the secondary side circuit in the second load state.

The control circuit of the secondary side circuit may synchronize the OOK with the reference clock signal. For example, the control circuit may switch to the first load state for a first clock period and switch to the second load state for a second clock period. The control circuit of the secondary side circuit may use a bit line coding scheme to ensure that the maximum off time for the switch is in a first load state (e.g., off or at a low load state) no more than fifty percent of the operating time of the secondary side circuit to prevent power interruptions to the control circuit. The maximum off time may be less than fifty percent of the operating time of the secondary side circuit. The bit line coding scheme may use an N+1 coding scheme where N is the number of bits in the data stream.

Although FIG. 5 discloses a particular number of operations related to method 500, method 500 may be executed with greater or fewer operations than those depicted in FIG. 5. In addition, although FIG. 5 discloses a certain order of operations to be taken with respect to method 500, the operations comprising method 500 may be completed in any suitable order.

Although examples have been described above, other variations and examples may be made from this disclosure without departing from the spirit and scope of these disclosed examples.

1. A transformer, comprising:
a primary side circuit;
a secondary side circuit; and
a control circuit communicatively coupled to the primary side circuit, the control circuit to:
generate an electrical signal to transmit a data signal and a clock signal from the primary side circuit to the secondary side circuit;
modulate the electrical signal, wherein the electrical signal is symmetrically modulated when the data signal is in an idle state and is asymmetrically modulated when the data signal is in an active state; and
transmit the electrical signal from the primary side circuit to the secondary side circuit.

2. The transformer of claim 1, wherein the control circuit is to align an edge of the electrical signal to a clock cycle.

3. The transformer of claim 1, wherein the electrical signal is asymmetrically modulated according to an alternating current free modulation scheme.

4. The transformer of claim 1, wherein the primary side circuit includes a pulse width modulation (PWM) circuit to modulate the electrical signal.

5. The transformer of claim 1, comprising:
a second primary side circuit;
a second secondary side circuit; and
wherein the control circuit is communicatively coupled to the second primary side circuit, the control circuit to:
generate a second electrical signal to transmit a second data signal and the clock signal from the second primary side circuit to the second secondary side circuit;
modulate the second electrical signal; and
transmit the second electrical signal from the second primary side circuit to the second secondary side circuit.

6. A transformer, comprising:
a primary side circuit;
a secondary side circuit; and
a control circuit communicatively coupled to the secondary side circuit, the control circuit to:
switch the secondary side circuit to a first load state to indicate an idle state of a data signal provided from the secondary side circuit to the primary side circuit; and
switch the secondary side circuit to a second load state to indicate an active state of the data signal; and
wherein switching between the first load state and the second load state is based on a bit line coding scheme.

7. The transformer of claim 6, wherein the bit line coding scheme contains at least one bit more than the data signal.

8. The transformer of claim 6, wherein the secondary side circuit is in the first load state for a time period less than a predetermined portion of an operating time of the secondary side circuit.

9. The transformer of claim 6, wherein switching between the first load state and the second load state uses on-off keying.

10. The transformer of claim 9, wherein switching between the first load state and the second load state is synced to a clock signal from the primary side circuit.

11. A method, comprising:
generating an electrical signal to transmit a data signal and a clock signal from a primary side circuit of a transformer to a secondary side circuit of the transformer;
modulating the electrical signal, wherein the electrical signal is symmetrically modulated when the data signal is in an idle state and is asymmetrically modulated when the data signal is in an active state; and
transmitting the electrical signal from the primary side circuit to the secondary side circuit.

12. The method of claim 11, comprising aligning an edge of the electrical signal to a clock cycle.

13. The method of claim 11, wherein the electrical signal is asymmetrically modulated according to an alternating current free modulation scheme.

14. The method of claim 11, comprising using a pulse width modulation (PWM) circuit to modulate the electrical signal.

15. The method of claim 11, comprising:
generating a second electrical signal to transmit a second data signal and the clock signal from a second primary side circuit of a second transformer to a second secondary side circuit of the second transformer;
modulating the second electrical signal; and
transmitting the second electrical signal from the second primary side circuit to the second secondary side circuit.

16. The method of claim 11, comprising:
switching the secondary side circuit to a first load state to indicate an idle state of a data signal provided from the secondary side circuit to the primary side circuit; and
switching the secondary side circuit to a second load state to indicate an active state of the data signal provided from the secondary side circuit to the primary side circuit; and
wherein switching between the first load state and the second load state is based on a bit line coding scheme.

17. The method of claim 16, wherein the bit line coding scheme contains at least one bit more than the data signal.

18. The method of claim 16, wherein the secondary side circuit is in the first load state for a time period less than a predetermined portion of an operating time of the secondary side circuit.

19. The method of claim 16, wherein switching between the first load state and the second load state uses on-off keying.

20. The method of claim 19, wherein switching between the first load state and the second load state is synced to the clock signal from the primary side circuit.
